(19) United States
(12) Patent Application Publication
(10) Pub. No.: US 2026/0190895 A1
(43) Pub. Date: Jul. 2, 2026

(54) APPARATUS AND METHOD FOR REMOVING METAL OXIDE ON SURFACE OF WAFER, AND SEMICONDUCTOR EQUIPMENT

(71) Applicant: AMBER INTELLIGENCE SEMICONDUCTOR EQUIPMENT (SHANGHAI) LTD., Shanghai (CN)

(72) Inventors: Zhanchao HUANG, Shanghai (CN); Tao SONG, Shanghai (CN); Xinggang ZHANG, Shanghai (CN)

(73) Assignee: AMBER INTELLIGENCE SEMICONDUCTOR EQUIPMENT (SHANGHAI) LTD., Shanghai (CN)

(21) Appl. No.: 19/502,833

(22) PCT Filed: Jun. 30, 2023
(86) PCT No.: PCT/CN2023/104442

§ 371 Date: Jan. 16, 2026

(30) Foreign Application Priority Data
May 18, 2023 (CN) 202310566818.9

(51) Int. Cl. H10P 70/00; C23C 14/02

(52) U.S. Cl. CPC H10P 70/20; C23C 14/021

(57) ABSTRACT

An apparatus and method for removing a metal oxide on a surface of a wafer, and semiconductor equipment are provided. The apparatus includes: a supporting platform, a heating module disposed in a treating chamber, and a gas inlet disposed in the treating chamber, where at least the surface of a wafer to be treated, which is located on the supporting platform, is heated to a first temperature by means of the heating module, and a treating gas containing an organic gas is introduced via the gas inlet to react with the metal oxide generated on the surface of the wafer to produce a metallic metastable-state compound; and at least the surface temperature of the wafer is then raised to a second temperature by means of heating with the heating module, such that the metallic metastable-state compound is decomposed, thereby resulting in a reduction of a metal therein.

### CROSS REFERENCE TO THE RELATED APPLICATIONS

This application is the national phase entry of International Application No. PCT/CN2023/104442, filed on Jun. 30, 2023, which is based upon and claims priority to Chinese Patent Application No. 202310566818.9, filed on May 18, 2023, the entire contents of which are incorporated herein by reference.

### TECHNICAL FIELD

The present disclosure relates to the technical field of semiconductor manufacturing, and in particular to, an apparatus and method for removing a metal oxide on a surface of a wafer and semiconductor equipment.

### BACKGROUND

In a manufacturing process of a semiconductor chip, a natural metal oxide layer is easily generated on a metal surface deposited on a surface of the semiconductor wafer (wafer). In a process of physical vapor deposition (PVD) equipment, to reduce the increase in contact resistance of the chip caused by the metal oxide, in a pre-cleaning chamber prior to metal deposition, a plasma or remote plasma method is typically employed to etch away these metal oxides, and then a metal is further deposited on the metal surface after the removal of the metal oxides to form interconnections or serve as a contact layer.

For nodes above 45 nm, the pre-cleaning chamber typically employs plasma generated by an inductively coupled plasma (ICP) or capacitively coupled plasma (CCP) method to remove the above metal oxides. However, for nodes at 45 nm and below, a dielectric layer with a low dielectric constant (low K) (typically lower than 3.9) is employed to reduce a resistor-capacitor delay (RC delay). The use of a low-k material prevents plasma from being used in pre-cleaning because the structure and properties of the low-k material will be damaged due to the bombardment effect of the plasma, such that a dielectric constant value (k value) of the material increases. Moreover, the bombardment will generate a large amount of heat, which results in a significant difference in the etching uniformity on the wafer surface, thereby affecting the performance of wafer manufacturing. Meanwhile, if a chamber is improperly designed, the plasma bombardment will be non-uniform, failing to achieve the objective of uniformly removing oxides; and such bombardment is prone to causing the problem of wafer arcing. Therefore, for nodes at 45 nm and below, the industry has begun employing methods such as remote plasma of hydrogen or nitrogen trifluoride (NF₃), where effective active groups are generated outside the chamber and transported into the chamber through gas transportation, enabling the active groups to react with oxides on the metal to remove the metal oxides. However, this method has the following defects: the chamber structure is more complex, the control difficulty is greater, the cost is also higher, and the speed of oxide removal is not fast enough.

In addition, in an advanced wafer-level packaging process, the PVD equipment is typically employed to deposit a metal redistribution layer (RDL) and under-bump metallization (UBM). Dielectric materials generally adopt organic materials such as polyimide/benzocyclobutene/dibenzoyl peroxide (PI/BCB/BPO). When plasma generated by ICP or CCP is used to remove metal oxides, these organic materials will generate carbon particles. Such particles adhere to the lining part (process kit) and are highly prone to falling off, which seriously affects the service life of the lining part (the service life a general lining part is usually equivalent to the etching of PI with a thickness of 25 μm), thereby severely affecting the throughput and cost of the equipment.

### SUMMARY

To overcome the above deficiencies in the prior art, an objective of the present disclosure is to provide an apparatus and method for removing a metal oxide on a surface of a wafer and semiconductor equipment.

To achieve the above objective, the present disclosure adopts the following technical solution:

The present disclosure provides an apparatus for removing a metal oxide on a surface of a wafer, including:
a treating chamber;
a supporting platform, disposed in the treating chamber and configured to support a wafer to be treated;
a heating module, disposed in the treating chamber and configured to heat the wafer; and
a gas inlet, disposed in the treating chamber and configured to introduce a treating gas containing an organic gas into the treating chamber;
where when at least the surface of the wafer is heated to a first temperature by means of the heating module, the treating gas containing a formic acid gas is introduced through the gas inlet, such that the formic acid gas in the treating gas reacts with the metal oxide generated on the surface of the wafer to form a metallic metastable-state compound, and at least the surface temperature of the wafer is raised to a second temperature by means of the heating module, such that the metallic metastable-state compound is decomposed, thereby resulting in a reduction of a metal therein.

Further, the treating gas containing the formic acid gas is a formic acid gas with argon as a carrier gas.

Further, the treating gas containing the formic acid gas is a formic acid gas with nitrogen as a carrier gas.

Further, the heating module includes a first heating module, and the first heating module is disposed in the supporting platform, located below the wafer, and configured to heat the wafer to the first temperature and the second temperature; or the heating module includes a second heating module, and the second heating module is disposed at a top inside the treating chamber, located above the wafer, and configured to heat at least the surface of the wafer to the first temperature and the second temperature.

Further, the heating module includes a first heating module and a second heating module, the first heating module is disposed in the supporting platform and located below the wafer, the second heating module is disposed at a top inside the treating chamber and located above the wafer, the first heating module is configured to heat the wafer to the first temperature, and the second heating module is configured to further heat at least the surface of the wafer to the second temperature.

Further, when the wafer is heated by means of the second heating module, the wafer is lifted up from the first heating module and moved close to the second heating module, or the second heating module is lowered from the top of the treating chamber and moved close to the wafer.

The present disclosure further provides semiconductor equipment, including a wafer transfer chamber, a plurality of process chambers around the wafer transfer chamber, and the above apparatus for removing a metal oxide on a surface of a wafer, where the apparatus is integrated on the wafer transfer chamber or any one of the process chambers.

Further, the equipment is configured to perform heat treatment on the wafer first by means of the apparatus for removing a metal oxide on a surface of a wafer and then perform a metal deposition process on the wafer by means of at least one process chamber.

The present disclosure further provides a method for removing a metal oxide on a surface of a wafer, including:
providing a treating chamber;
transferring a wafer to be treated to a supporting platform in the treating chamber;
heating the wafer to a first temperature, and then introducing a treating gas containing a formic acid gas into the treating chamber, such that the formic acid gas in the treating gas reacts with the metal oxide generated on the surface of the wafer to form a metallic metastable-state compound; and
raising at least the surface temperature of the wafer to a second temperature, such that the metallic metastable-state compound is decomposed, thereby resulting in a reduction of a metal therein.

Further, the metal oxide includes an oxide of Sn, Cu, Pb, Ni, Au, Al, Pt, Co or Ag, or includes an oxide of an alloy of at least two of Sn, Cu, Pb, Ni, Au, Al, Pt, Co or Ag.

Further, a volume concentration of an organic gas in the treating gas is 0.5% to 10%.

Further, the treating gas containing the formic acid gas is a formic acid gas with argon as a carrier gas.

Further, the treating gas containing the formic acid gas is a formic acid gas with nitrogen as a carrier gas.

Further, the first temperature is 100° C. to 250° C., and/or the second temperature is 180° C. to 450° C.

It may be seen from the above technical solution that by disposing the treating chamber through which the treating gas containing the organic gas may be introduced and that has the heating function, at a certain temperature (first temperature), the metal oxide generated on the surface of the wafer is treated by means of the organic gas (such as the formic acid gas) in the treating gas, such that the organic gas reacts with the metal oxide to generate the metallic metastable-state compound with unstable properties, and then the temperature is raised (to the second temperature), such that the metallic metastable-state compound is decomposed, thereby resulting in the reduction of a metal therein. According to the present disclosure, by introducing the treating gas containing the organic gas into the specific chamber, and controlling the concentration of the organic gas and the temperature of the wafer, the oxide of the metal surface in wafer manufacturing may be effectively removed by employing the heat treatment method without introducing plasma to bombard the surface of the wafer and generating the bombardment defect on the wafer surface, which provides an oxide-free metal layer surface for subsequent metal deposition steps, thereby reducing the series resistance of interconnections. The technology of the present disclosure is simple and easy to control. The present disclosure not only simplifies the apparatus structure and improves the removal efficiency of metal oxides, but also avoids the problems of wafer arcing and damage to the dielectric layer caused by plasma bombardment. The present disclosure can be further applied to advanced wafer-level packaging, which may significantly reduce generation of particles in the chamber during cleaning, prolong the service time of the chamber, save the material cost, and improve the production efficiency, thereby, lowering the cost of the equipment.

### BRIEF DESCRIPTION OF THE DRAWINGS

FIG. 1 is a schematic structural diagram of an apparatus for removing a metal oxide on a surface of a wafer in a preferred embodiment of the present disclosure;

FIG. 2 is a schematic structural diagram of a planar layout of semiconductor physical vapor deposition (PVD) equipment in preferred embodiment of the present disclosure.

### DETAILED DESCRIPTION OF THE EMBODIMENTS

To make the objectives, technical solutions, and advantages of the embodiments of the present disclosure clearer, the technical solutions in the embodiments of the present disclosure will be described clearly and completely below. Apparently, the described embodiments are part of the embodiments of the present disclosure, rather than all the embodiments. Based on the embodiments of the present disclosure, all other embodiments obtained by those of ordinary skill in the art without making creative efforts shall fall within the protection scope of the present disclosure. Unless otherwise defined, the technical terms or scientific terms used herein shall have the ordinary meanings understood by those of ordinary skill in the art to which the present disclosure pertains. The term “comprising” and similar words used herein mean that the elements or articles preceding the term includes the elements or articles listed after the term and equivalents thereof, without excluding other elements or articles.

Specific embodiments of the present disclosure will be further described in detail below in conjunction with drawings.

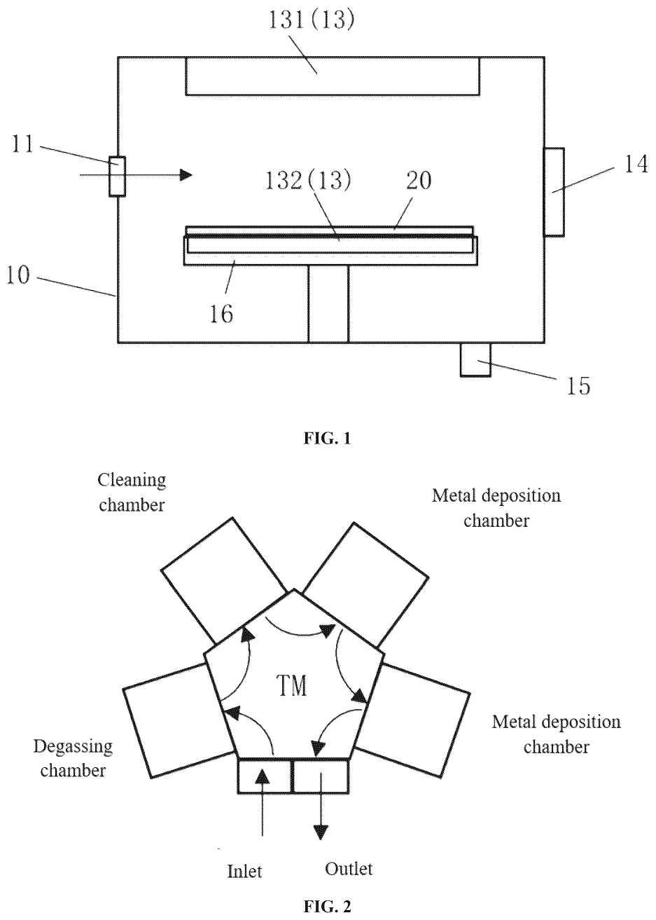

Referring to FIG. 1, FIG. 1 is a schematic structural diagram of an apparatus for removing a metal oxide on a surface of a wafer in a preferred embodiment of the present disclosure. As shown in FIG. 1, an apparatus for removing a metal oxide on a surface of a wafer provided by the present disclosure includes a treating chamber 10, a supporting platform 16 and a heating module 13 disposed in the treating chamber 10, and a gas inlet 11, an exhaust port 15, and a transfer window 14 disposed in a chamber wall of the treating chamber 10.

The supporting platform 16 is disposed inside the treating chamber 10 and may be located at a bottom of the treating chamber 10. The supporting platform 16 is configured to support a wafer 20 to be treated.

The wafer 20 may be, for example, a semiconductor wafer. The wafer 20 to be treated may be transferred through the transfer window 14 to enter the treating chamber 10 and is placed on the supporting platform 16 for treatment. A valve may be disposed in the transfer window 14 to isolate the treating chamber 10 from outside.

At least one gas inlet 11 may be disposed in a side wall of the treating chamber 10, and is configured to introduce a treating gas containing an organic gas into the treating chamber 10. An installation height of the gas inlet 11 in the side wall of the treating chamber 10 should be typically higher than an installation height of the supporting platform 16 in the treating chamber 10, such that when introduced from the gas inlet 11 to the treating chamber 10, the treating gas can easily flow to cover the surface of the wafer 20 to treat the metal surface exposed to the surface of the wafer 20.

For example, a metal interconnection layer or an RDL and UBM deposited during advanced wafer-level packaging may be manufactured on the wafer 20 to be treated, and a natural metal oxide will be generated on an exposed surface of the interconnected metal on the metal interconnection layer or an exposed surface of the RDL or UBM. To reduce the increase in contact resistance of the chip caused by metal oxides, prior to subsequent metal deposition, it is needed to remove the metal oxides first, and then a novel metal is continuously deposited on the metal surface after the removal of the metal oxides to form interconnections or serve as a contact layer.

An exhaust port 15 may be disposed in a bottom surface of the treating chamber 10 and configured to discharge a tail gas generated in the treatment process out of the treating chamber 10.

The heating module 13 is disposed in the treating chamber 10, and configured to heat the wafer 20, such that the wafer 20 receives treatment by the treating gas at a certain temperature.

During the treatment, the wafer 20 to be treated placed on the supporting platform 16 is heated first by means of the heating module 13, and a part of at least the surface of the wafer 20 or the overall wafer 20 is heated to a first temperature higher than room temperature. In this case, the treating gas containing a formic acid gas into the treating chamber 10 through the gas inlet 11, such that the formic acid gas in the treating gas reacts with the metal oxide generated on the surface of the wafer 20 to form a metallic metastable-state compound. After the reaction is finished, the temperature of the part of at least the surface of the wafer 20 or the overall temperature of the wafer 20 is further raised to a second temperature by means of heating with the heating module 13. Since the above-mentioned metallic metastable-state compound is an intermetallic compound with unstable properties, the metallic metastable-state compound can be decomposed at a relatively high temperature, such that the metal in the metallic metastable-state compound is reduced and combined on the surface of the original metal. Other gaseous or vaporized decomposition products generated in the reaction may be extracted out of the treating chamber 10 under a negative pressure action of the exhaust port 15. Thus, the oxide of the metal growing on the surface of the original metal may be removed, and the treated surface of the metal is exposed. Then, the treated wafer 20 may be transferred out of the treating chamber 10 again through the transfer window 14 and may enter a next PVD or CVD process.

By employing the organic gas to remove the oxide on the metal surface on the wafer 20 by heat treatment, the metal oxides on the wafer 20 may be effectively removed without introducing plasma or active atomic groups, which can not only simplify the apparatus structure and improve the removal efficiency of metal oxides, but also avoid the problems of wafer arcing and damage to the dielectric layer caused by plasma bombardment. When applied to advanced wafer-level packaging, the present disclosure may further significantly reduce generation of particles in the chamber during cleaning, prolong the service time of the chamber, save the material cost, and improve the production efficiency, thereby, lowering the cost of the equipment.

Referring to FIG. 1, in some embodiments, the heating module 13 includes a first heating module 132 and a second heating module 131. The first heating module 132 may be disposed in the supporting platform 16 and located below the wafer 20. The second heating module 131 may be disposed at a top inside the treating chamber 10 and correspondingly located above the wafer 20. The first heating module 132 is configured to heat the wafer 20 to a first temperature, and the second heating module 131 is configured to further heat a part of at least the surface of the wafer 20 to a second temperature. When the metal oxides on the surface of the wafer 20 are removed, the temperature of the wafer 20 may be raised to the first temperature by initiating the first heating module 132. Then, the treating gas containing the organic gas may be introduced through the gas inlet 11 to react with the metal oxides. After the reaction is finished, the temperature of the part of at least the surface of the wafer 20 is further raised to the second temperature by initiating the second heating module 131, such that a reaction product located on the surface of the wafer 20 is decomposed and discharged through the exhaust port 15, so as to expose the metal surface on the surface of the wafer 20.

In some embodiments, the first heating module 132 and the second heating module 131 may be resistance heaters or heating lamps, or may be other applicable heating equipment.

In this embodiment, the first heating module 132 may be the resistance heater, and the second heating module 131 may be the heating lamp.

Further, when the wafer 20 is heated by means of the second heating module 131 and the temperature of the wafer 20 is raised, the heating temperature of the first heating module 132 may be maintained at the first temperature, and the wafer 20 may be lifted up from the first heating module 132 by means of a lifting ejector pin disposed in the supporting platform 16, leaves the first heating module 132, and is moved close to the second heating module 131, such that the wafer 20 is rapidly heated by the second heating module 131 more effectively. Alternatively, the second heating module 131 is moved close to the wafer 20 by way of lowering the second heating module 131 from the top of the treating chamber 10 through a lifting mechanism, so as to more effectively and rapidly heat the wafer 20.

In other embodiments, the heating module 13 may also only include the first heating module 132. In this case, the first heating module 132 may be disposed in the supporting platform 16 and located below the wafer 20. Moreover, the wafer 20 may be heated step by step by means of the first heating module 132, such that the wafer 20 is heated to different temperatures. That is, the temperature of the wafer 20 is raised to the first temperature first through the first heating module 132, such that the metal oxides on the wafer 20 react with the organic gas at this temperature. After the reaction is finished, the temperature of the wafer 20 is further raised to the second temperature through the first heating module 132, such that reaction products of the metal oxides and the organic gas are decomposed and can be discharged. In this embodiment, the first heating module 132 is preferably the heating lamp, to increase the heating rate. The gas inlet 11 may also be disposed on the top inside the treating chamber 10 and located above the wafer 20.

Alternatively, the heating module 13 may also only include the second heating module 131. In this case, the second heating module 131 may be disposed at the top inside the treating chamber 10 and located above the wafer 20. Moreover, the wafer 20 may be heated step by step through the second heating module 131, such that the wafer 20 is heated to different temperatures. That is, the temperature of a part of at least the surface of the wafer 20 is raised to the first temperature first through the second heating module 131, such that the metal oxides on the wafer 20 react with the organic gas at this temperature. After the reaction is finished, the temperature of a part of at least the surface of the wafer 20 is further raised to the second temperature through the second heating module 131, such that reaction products of the metal oxides and the organic gas are decomposed and can be discharged. In this embodiment, the second heating module 131 is preferably the heating lamp, to increase the heating rate.

In some embodiments, the present disclosure may be used for removing oxides of corresponding metals generated on patterned surfaces of metals Sn, Cu, Pb, Ni, Au, Al, Pt, Co or Ag on the wafer 20 by heat treatment and removing oxides of an alloy of at least two of the metals Sn, Cu, Pb, Ni, Au, Al, Pt, Co and Ag on the wafer 20 by heat treatment.

In a preferred embodiment of the present disclosure, the treating gas containing the formic acid gas is a formic acid gas with argon as a carrier gas.

In another preferred embodiment of the present disclosure, the treating gas containing the formic acid gas is a formic acid gas with nitrogen as a carrier gas.

In some other embodiments of the present disclosure, the treating gas containing the formic acid gas is a formic acid gas with other gases except for argon or nitrogen as a carrier gas.

That is, an apparatus for removing a metal oxide on a surface of a wafer provided in a preferred embodiment of the present disclosure includes:
a treating chamber;
a supporting platform, disposed in the treating chamber and configured to support a wafer to be treated;
a heating module, disposed in the treating chamber and configured to heat the wafer; and
a gas inlet, disposed in the treating chamber and configured to introduce a treating gas containing an organic gas into the treating chamber;
where when at least the surface of the wafer is heated to a first temperature by means of the heating module, the treating gas containing a formic acid gas is introduced through the gas inlet, such that the formic acid gas in the treating gas reacts with the metal oxide generated on the surface of the wafer to form a metallic metastable-state compound, and at least the surface temperature of the wafer is raised to a second temperature, such that the metallic metastable-state compound is decomposed, thereby resulting in a reduction of a metal therein; where the treating gas containing the formic acid gas is a formic acid gas with argon as a carrier gas.

That is, an apparatus for removing a metal oxide on a surface of a wafer provided in another preferred embodiment of the present disclosure includes:
a treating chamber;
a supporting platform, disposed in the treating chamber and configured to support a wafer to be treated;
a heating module, disposed in the treating chamber and configured to heat the wafer; and
a gas inlet, disposed in the treating chamber and configured to introduce a treating gas containing an organic gas into the treating chamber;
where when at least the surface of the wafer is heated to a first temperature by means of the heating module, the treating gas containing a formic acid gas is introduced through the gas inlet, such that the formic acid gas in the treating gas reacts with the metal oxide generated on the surface of the wafer to form a metallic metastable-state compound, and at least the surface temperature of the wafer is raised to a second temperature, such that the metallic metastable-state compound is decomposed, thereby resulting in a reduction of a metal therein; where the treating gas containing the formic acid gas is a formic acid gas with nitrogen as a carrier gas.

In the above embodiment, regardless of whether the treating gas containing a formic acid gas is the formic acid gas with argon as the carrier gas or the formic acid gas with nitrogen as the carrier gas, the formic acid gas in the treating gas may be more effectively delivered into the chamber and reacts with the metal oxide on the surface of the wafer to generate the metallic metastable-state compound.

In some embodiments, the organic gas may be carried by the carrier gas and introduced into the treating chamber 10 from the gas inlet 11. Therefore, the carrier gas and the organic gas form the treating gas. A volume concentration of an organic gas in the treating gas is 0.5% to 10%.

In some embodiments, the organic gas may include an organic acid gas such as a carboxylic acid gas, specifically a formic acid (HCOOH) gas. For example, when the treated metal is Sn or Pb, the volume concentration of the introduced formic acid gas may be 0.66% or higher; when the treated metal is Cu or Al, the volume concentration of the introduced formic acid gas may be 2% to 4%; and when the treated metal is Au, Ag, Pt or Ni, the volume concentration of the introduced formic acid gas may be 1.7% or higher.

In some embodiments, the first temperature may be 100° C. to 250° C.

In some embodiments, the second temperature may be 180° C. to 450° C.

Referring to FIG. 2, semiconductor equipment provided by the present disclosure includes a wafer transfer chamber (TM, Transfer Module), a plurality of process chambers around the wafer 20 transfer chamber, and the apparatus for removing a metal oxide on a surface of a wafer provided by the present disclosure. Moreover, the apparatus for removing a metal oxide on a surface of a wafer may be integrated on the wafer transfer chamber or any one of the process chambers.

In some embodiments, the semiconductor equipment may be PVD equipment with a plurality of chambers. For example, the PVD equipment may be provided with one transfer chamber TM and four process chambers around the transfer chamber. The process chambers may include a degassing chamber, a cleaning chamber, and two metal deposition chambers. The transfer chamber is provided with a wafer inlet and a wafer outlet. Typically, the wafer 20 to be deposited with a metal is transferred to the transfer chamber from the wafer inlet, and transferred in sequence among the degassing chamber, the cleaning chamber, and the metal deposition chamber to perform degassing, cleaning, and metal deposition processes, so as to form a metal pattern (including a metal interconnection layer or an RDL and UBM deposited during advanced wafer-level packaging) disposed in the wafer 20. Before entering the PVD equipment, the wafer 20 probably has the metal pattern, and a metal oxide has been generated on the surface of the metal pattern; alternatively, during the stage when the wafer 20 enters the PVD equipment and between multiple metal deposition processes, the metal oxide will also be generated on the surface of the metal pattern deposited in the previous process. In this case, the apparatus (treating chamber 10) for removing a metal oxide on a surface of a wafer provided by the present disclosure may be integrated on the transfer chamber or the cleaning chamber, and the wafer 20 to be treated is transferred into the treating chamber 10 of the apparatus provided by the present disclosure. Heat treatment may be performed on the wafer 20 first by employing, for example, the treating gas containing the formic acid gas, to remove the metal oxide generated on the previous metal surface before each metal deposition. Then, the wafer 20 after the metal oxide is removed is transferred into other process chambers for PVD metal deposition process treatment.

The method for removing a metal oxide on a surface of a wafer provided by the present disclosure may be further described in detail below in conjunction with specific embodiments and drawings.

The method for removing a metal oxide on a surface of a wafer provided by the present disclosure may be implemented employing the apparatus (semiconductor equipment) for removing a metal oxide on a surface of a wafer provided by the present disclosure and may include the following steps:
Step S1: a treating chamber 10 is provided;
Step S2: a wafer 20 to be treated is transferred to a supporting platform 16 in the treating chamber 10;
Step S3: the wafer 20 is heated to a first temperature, and then a treating gas containing a formic acid gas is introduced into the treating chamber 10, such that the formic acid gas in the treating gas reacts with the metal oxide generated on the surface of the wafer 20 to form a metallic metastable-state compound; and
Step S4: at least the surface temperature of the wafer 20 is raised to a second temperature, such that the metallic metastable-state compound is decomposed, thereby resulting in a reduction of a metal therein.

In a preferred embodiment of the present disclosure, the treating gas containing the formic acid gas is a formic acid gas with argon as a carrier gas.

In another embodiment of the present disclosure, the treating gas containing the formic acid gas is a formic acid gas with nitrogen as a carrier gas.

In some other embodiments of the present disclosure, the treating gas containing the formic acid gas is a formic acid gas with other gases except for argon or nitrogen as a carrier gas.

That is, the method for removing a metal oxide on a surface of a wafer provided in a preferred embodiment of the present disclosure includes:
a treating chamber is provided;
a wafer to be treated is transferred to a supporting platform in the treating chamber;
the wafer is heated to a first temperature, and then a treating gas containing a formic acid gas is introduced into the treating chamber, such that the formic acid gas in the treating gas reacts with the metal oxide generated on the surface of the wafer to form a metallic metastable-state compound, where the treating gas containing the formic acid gas is a formic acid gas with argon as a carrier gas;
at least the surface temperature of the wafer is raised to a second temperature, such that the metallic metastable-state compound is decomposed, thereby resulting in a reduction of a metal therein.

That is, the method for removing a metal oxide on a surface of a wafer provided in another preferred embodiment of the present disclosure includes:
a treating chamber is provided;
a wafer to be treated is transferred to a supporting platform in the treating chamber;
the wafer is heated to a first temperature, and then a treating gas containing a formic acid gas is introduced into the treating chamber, such that the formic acid gas in the treating gas reacts with the metal oxide generated on the surface of the wafer to form a metallic metastable-state compound, where the treating gas containing the formic acid gas is a formic acid gas with nitrogen as a carrier gas;
at least the surface temperature of the wafer is raised to a second temperature, such that the metallic metastable-state compound is decomposed, thereby resulting in a reduction of a metal therein.

In the above embodiment, regardless of whether the treating gas containing a formic acid gas is the formic acid gas with argon as the carrier gas or the formic acid gas with nitrogen as the carrier gas, the formic acid gas in the treating gas may be better guided into the chamber and reacts with the metal oxide on the surface of the wafer to generate the metallic metastable-state compound. Referring to FIGS. 1-2, in the following one example, in an integrated circuit manufacturing process, the interconnecting layer metal may be deposited by way of PVD. For example, a metal diffusion barrier layer and a seed layer in a through hole are deposited, a metal gate is deposited, and a metal for forming metal silicide is deposited. In a standard PVD process, the equipment is typically provided with three different process chambers: the degassing chamber, the cleaning chamber, and the metal deposition chamber. In the degassing chamber, vapor on the surface of the wafer 20 (wafer) is removed by high temperature; in the cleaning chamber, the oxide on the metal is cleaned through plasma or some active groups; and then, the wafer 20 is transferred out to the metal deposition chamber (PVD) for metal deposition.

In this embodiment, the treating chamber 10 of the apparatus provided by the present disclosure may be integrated on the transfer chamber, and isolation from the transfer chamber is controlled by means of the valve on the transfer window 14. The wafer 20 may be controlled to be heated respectively through the bottom heater (the first heating module 132) disposed in the supporting platform 16 and the top heater (the second heating module 131) disposed at the top of the treating chamber 10. For example, the surface of the entering wafer 20 to be treated has a wiring of a metal Cu, and in this case, the temperature of the bottom heater is controlled at 150° C. After the wafer 20 enters the treating chamber 10, the valve on the transfer window 14 is closed. Then, the formic acid gas with nitrogen or argon as the carrier gas is introduced through the gas inlet 11, and flows of formic acid and carrier gas are adjusted according to a process requirement to adjust the percentage concentration of the formic acid gas entering the treating chamber 10. According to the process requirement, the chamber pressure of the treating chamber 10 may be, for example, adjusted between 1 mbar and 980 mbar. The wafer 20 is treated at 150° C. for 5 s to 300 s to ensure that the oxide on the metal surface reacts completely to form the unstable metallic metastable-state compound (Cu(COOH)₂). Then, the top heater is started to raise the temperature of the wafer 20 to 200° C. or higher for heat treatment, such that the unstable metallic metastable-state compound is decomposed. According to the process effect, the heat treatment time may be 1 s to 300 s. After treatment, introduction of the treating gas is stopped, and the pressure of the treating chamber 10 is evacuated to a vacuum state through the exhaust port 15. Finally, the valve on the transfer window 14 may be opened to transfer the wafer 20 after the metal oxide is removed out for subsequent metal deposition process treatment.

The basic principle of removing the metal oxide by means of formic acid is introduced below:

### Reduction Reaction of Formic Acid:

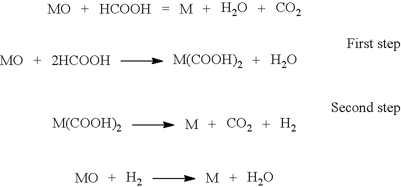

where MO represents the metal oxide, and HCOOH represents formic acid.

Referring to FIGS. 1-2, in the following another example, in advanced wafer-level packaging, the RDL and UBM will be deposited by way of PVD. Materials of a dielectric layer typically adopt organic materials such as polyimide/benzocyclobutene/dibenzoyl peroxide (PI/BCB/BPO). In a standard PVD process, the equipment is typically provided with three different process chambers: the degassing chamber, the cleaning chamber, and the metal deposition chamber. In the degassing chamber, vapor on the surface of the wafer 20 (wafer) is removed by high temperature; in the cleaning chamber, the oxide on the metal is cleaned typically through plasma by way of ICP or CCP; and then, the wafer 20 is transferred out to the metal deposition chamber (PVD chamber) for metal deposition. Since PI/BCB/BPO is the organic material, many organic carbon particles will be generated in the plasma treating process. Such particles cannot adhere to the lining part (process kit) effectively, resulting in the service life of a general lining part usually equivalent to the etching of PI with a thickness of 25 μm, thereby severely affecting the throughput and cost of the equipment.

In this embodiment, the treating chamber 10 of the apparatus provided by the present disclosure is integrated on the transfer chamber TM, and isolation from the transfer chamber is controlled through the valve on the transfer window 14. The wafer 20 may be controlled to be heated respectively through the bottom heater (the first heating module 132) disposed in the supporting platform 16 and the top heater (the second heating module 131) disposed at the top of the treating chamber 10. For example, the surface of the entering wafer 20 to be treated has a wiring of a metal Cu, and in this case, the temperature of the bottom heater is controlled at 180° C. After the wafer 20 enters the treating chamber 10, the valve on the transfer window 14 is closed. Then, the formic acid gas with nitrogen or argon as the carrier gas is introduced through the gas inlet 11, and flows of formic acid and carrier gas are adjusted according to a process requirement to adjust the percentage concentration of the formic acid gas entering the treating chamber 10. According to the process requirement, the chamber pressure of the treating chamber 10 may be, for example, adjusted between 1 mbar and 980 mbar. The wafer 20 is treated at 180° C. for 5 s to 300 s to ensure that the oxide on the metal surface reacts completely to form the unstable metallic metastable-state compound (Cu(COOH)₂). Then, the top heater is started to raise the temperature of the wafer 20 to 250° C. or higher for heat treatment, such that the unstable metallic metastable-state compound is decomposed. According to the process effect, the heat treatment time may be 1 s to 300 s. After treatment, introduction of the treating gas is stopped, and the pressure of the treating chamber 10 is evacuated to a vacuum state through the exhaust port 15. Finally, the valve on the transfer window 14 may be opened to transfer the wafer 20 after the metal oxide is removed out for subsequent metal deposition process treatment.

The above heat treatment method for formic acid is a heat treatment method. The formic acid reacts with the oxide on the metal surface to expose the underlying metal. By employing the heat treatment method, commonly used plasma at present is not introduced, such that the bombardment on the low-k dielectric layer around the metal wiring is greatly reduced and the low-k properties are retained. Moreover, the heat treatment method reduces C particles generated by plasma bombardment in advanced packaging, such that the service life of the lining part inside the pre-cleaning chamber (including the treating chamber 10 of the present disclosure) is greatly prolonged.

The treating chamber 10 of the apparatus provided by the present disclosure is simple in structure, and a clean wafer (wafer 20) without a metal oxide layer may be obtained by forming the gas inlet 11 for the formic acid gas and treating the wafer by means of bottom heating and top heating or other heating methods. Therefore, the present disclosure is particularly applicable to some PVD equipment with low line width (45 nm) in advanced wafer-level packaging, and features a simple method, a reduced cost, and ease of control.

Although various possible embodiments of the present disclosure have been described in detail above, it will be apparent to those skilled in the art that various combinations, modifications, and variations of technical features can be made to these embodiments. However, it should be understood that such combinations, modifications, and variations of technical features fall within the scope and spirit of the present disclosure as set forth in the claims. Furthermore, the present disclosure described herein may have other embodiments and can be implemented or realized in various ways.

What is claimed is:

1. A method for removing a metal oxide on a surface of a wafer, comprising:
providing a treating chamber;
transferring the wafer to a supporting platform in the treating chamber;
heating the wafer to a first temperature, and then introducing a treating gas containing a formic acid gas into the treating chamber, such that the formic acid gas in the treating gas reacts with the metal oxide generated on the surface of the wafer to form a metallic metastable-state compound;
raising at least a surface temperature of the wafer to a second temperature, such that the metallic metastable-state compound is decomposed, thereby resulting in a reduction of a metal therein.

2. The method for removing the metal oxide on the surface of the wafer according to claim 1, wherein the metal oxide comprises an oxide of Sn, Cu, Pb, Ni, Au, Al, Pt, Co, or Ag, or comprises an oxide of an alloy of at least two of Sn, Cu, Pb, Ni, Au, Al, Pt, Co, or Ag.

3. The method for removing the metal oxide on the surface of the wafer according to claim 1, wherein a volume concentration of an organic gas in the treating gas is 0.5% to 10%.

4. The method for removing the metal oxide on the surface of the wafer according to claim 1, wherein the first temperature is 100° C. to 250° C., and/or the second temperature is 180° C. to 450° C.

5. An apparatus for removing a metal oxide on a surface of a wafer, comprising:
a treating chamber;
a supporting platform, disposed in the treating chamber and configured to support the wafer;
a heating module, disposed in the treating chamber and configured to heat the wafer; and
a gas inlet, disposed in the treating chamber and configured to introduce a treating gas containing an organic gas into the treating chamber;
wherein when at least the surface of the wafer is heated to a first temperature by the heating module, the treating gas containing a formic acid gas is introduced through the gas inlet, such that the formic acid gas in the treating gas reacts with the metal oxide generated on the surface of the wafer to form a metallic metastable-state compound, and at least a surface temperature of the wafer is raised to a second temperature by the heating module, such that the metallic metastable-state compound is decomposed, thereby resulting in a reduction of a metal therein.

6. The apparatus for removing the metal oxide on the surface of the wafer according to claim 5, wherein the heating module comprises a first heating module, and the first heating module is disposed in the supporting platform, located below the wafer, and configured to heat the wafer to the first temperature and the second temperature; or the heating module comprises a second heating module, and the second heating module is disposed at a top inside the treating chamber, located above the wafer, and configured to heat at least the surface of the wafer to the first temperature and the second temperature.

7. The apparatus for removing the metal oxide on the surface of the wafer according to claim 5, wherein the heating module comprises a first heating module and a second heating module, the first heating module is disposed in the supporting platform and located below the wafer, the second heating module is disposed in a top inside the treating chamber and located above the wafer, the first heating module is configured to heat the wafer to the first temperature, and the second heating module is configured to further heat at least the surface of the wafer to the second temperature.

8. The apparatus for removing the metal oxide on the surface of the wafer according to claim 7, wherein when the wafer is heated by the second heating module, the wafer is lifted up from the first heating module and moved close to the second heating module, or the second heating module is lowered from the top of the treating chamber and moved close to the wafer.

9. A semiconductor equipment, comprising a wafer transfer chamber, a plurality of process chambers around the wafer transfer chamber, and the apparatus for removing the metal oxide on the surface of the wafer according to claim 5, wherein the apparatus is integrated on the wafer transfer chamber or one of the plurality of process chambers.

10. The semiconductor equipment according to claim 9, wherein the semiconductor equipment is configured to perform heat treatment on the wafer first by the apparatus for removing the metal oxide on the surface of the wafer and then perform a metal deposition process on the wafer by at least one of the plurality of process chambers.

11. The semiconductor equipment according to claim 9, wherein in the apparatus, the heating module comprises a first heating module, and the first heating module is disposed in the supporting platform, located below the wafer, and configured to heat the wafer to the first temperature and the second temperature; or the heating module comprises a second heating module, and the second heating module is disposed at a top inside the treating chamber, located above the wafer, and configured to heat at least the surface of the wafer to the first temperature and the second temperature.

12. The semiconductor equipment according to claim 9, wherein in the apparatus, the heating module comprises a first heating module and a second heating module, the first heating module is disposed in the supporting platform and located below the wafer, the second heating module is disposed in a top inside the treating chamber and located above the wafer, the first heating module is configured to heat the wafer to the first temperature, and the second heating module is configured to further heat at least the surface of the wafer to the second temperature.

13. The semiconductor equipment according to claim 12, wherein in the apparatus, when the wafer is heated by the second heating module, the wafer is lifted up from the first heating module and moved close to the second heating module, or the second heating module is lowered from the top of the treating chamber and moved close to the wafer.

14. The semiconductor equipment according to claim 11, wherein the semiconductor equipment is configured to perform heat treatment on the wafer first by the apparatus for removing the metal oxide on the surface of the wafer and then perform a metal deposition process on the wafer by at least one of the plurality of process chambers.

15. The semiconductor equipment according to claim 12, wherein the semiconductor equipment is configured to perform heat treatment on the wafer first by the apparatus for removing the metal oxide on the surface of the wafer and then perform a metal deposition process on the wafer by at least one of the plurality of process chambers.

16. The semiconductor equipment according to claim 13, wherein the semiconductor equipment is configured to perform heat treatment on the wafer first by the apparatus for removing the metal oxide on the surface of the wafer and then perform a metal deposition process on the wafer by at least one of the plurality of process chambers.
